(19) United States
(12) Patent Application Publication
(10) Pub. No.: US 2017/0054104 A1
(43) Pub. Date: Feb. 23, 2017

(54) DISPLAY DEVICE AND METHOD OF MANUFACTURING THE SAME

(71) Applicant: Samsung Display Co., Ltd., Yongin-si (KR)

(72) Inventors: Jaekyung Go, Yongin-si (KR); Hyunjun Choi, Yongin-si (KR); Eunjae Na, Yongin-si (KR); Seyeon Oh, Yongin-si (KR); Hyunmin Hwang, Yongin-si (KR)

(21) Appl. No.: 15/090,403

(22) Filed: Apr. 4, 2016

(30) Foreign Application Priority Data
Aug. 19, 2015 (KR) 10-2015-0116850

(51) Int. Cl. H01L 51/52; H01L 27/32; H01L 51/56

(52) U.S. Cl. CPC H01L 51/5246; H01L 51/5243; H01L 51/56; H01L 27/3244; H01L 2251/566; H01L 2227/323

(57) ABSTRACT

A display device and a method of manufacturing the same are disclosed. In one aspect, the display device includes a first substrate, a display unit disposed over the first substrate and a second substrate located over the display unit. The display device also includes a sealing portion disposed outside the display unit and between the first and second substrates, wherein the sealing portion includes a first part extending along a first edge of the first substrate, and wherein the first part comprises an outer side surface that is located on the same surface as an outer side surface of the first substrate. According to embodiments, the display device can reduce a defect rate during manufacturing.

### CROSS-REFERENCE TO RELATED APPLICATION

This application claims the benefit of Korean Patent Application No. 10-2015-0116850, filed on Aug. 19, 2015, in the Korean Intellectual Property Office, the disclosure of which is incorporated herein in its entirety by reference.

### BACKGROUND

Field

The described technology generally relates to a display device and a method of manufacturing the same.

Description of the Related Technology

In general, when a display device is manufactured, a plurality of display units that are spaced apart from each other are formed on a first mother substrate, a second mother substrate is attached to the first mother substrate. Thereafter, the first and second mother substrates are cut to form a plurality of display panels at the same time.

However, defects can occur when cutting the first and second mother substrates, and accordingly, a plurality of display panels may have defects.

### SUMMARY OF CERTAIN INVENTIVE ASPECTS

One inventive aspect is a display device that can reduce a defective rate during manufacturing, and a method of manufacturing the display device.

Another aspect is a display device that includes: a first substrate; a display unit disposed on the first substrate; a second substrate located above the first substrate with the display unit between the first and second substrates; and a sealing portion disposed outside the display unit and between the first substrate and the second substrate, wherein a first part of the sealing portion, which is at least a part of the sealing portion extending along a first edge of the first substrate comprises an outer side surface that is located at a same surface as an outer side surface of the first substrate.

The display device may further comprise a pad disposed on the first substrate to be adjacent to a third edge of the first substrate.

A direction in which the first edge extends may cross a direction in which the third edge extends.

The sealing portion may surround the display unit.

The display device may further comprise a pad disposed on the first substrate to be adjacent to a third edge of the first substrate, wherein the pad is located outside of the sealing portion.

A distance between an inner side surface of the first part of the sealing portion and the display unit may be greater than a distance between an inner side surface of a second part of the sealing portion and the display unit, wherein the second part is at least a part of the sealing portion extending along a second edge of the first substrate that is opposite to the first edge of the first substrate.

The sealing portion may bond the first substrate to the second substrate by an irradiated laser beam.

Another aspect is a display device that includes a first substrate; a display unit disposed on the first substrate; a second substrate located above the first substrate with the display unit between the first substrate and the second substrate; and a sealing portion disposed outside the display unit and between the first substrate and the second substrate, wherein a first part that is at least a part of the sealing portion extending along a first edge of the first substrate has a width that is greater than a width of a second part that is at least a part of the sealing portion extending along a second edge of the first substrate that is opposite to the first edge of the first substrate.

The display device may further comprise a pad disposed on the first substrate to be adjacent to a third edge of the first substrate.

A direction in which the first edge extends may cross a direction in which the third edge extends.

The sealing portion may surround the display unit.

The display device may further comprise a pad disposed on the first substrate to be adjacent to a third edge of the first substrate, wherein the pad is located outside of the sealing portion.

An outer side surface of the first part of the sealing portion may be located at a same surface as an outer side surface of the first substrate.

A distance between an inner side surface of the first part of the sealing portion and the display unit may be equal to a distance between an inner side surface of the second part of the sealing portion and the display unit.

The display device may further comprise a metal layer between the first substrate and the sealing portion to correspond to the sealing portion, wherein the metal layer has a width corresponding to the first part of the sealing portion to be greater than a width corresponding to the second part of the sealing portion.

The sealing portion may bond the first substrate to the second substrate by an irradiated laser beam.

Another aspect is a method of manufacturing a display device, that comprises: forming a plurality of display units and a plurality of pads corresponding to the plurality of display units on a first mother substrate; bonding the first mother substrate to a second mother substrate so that the plurality of display units are located inside, and a plurality of sealing portions disposed respectively outside the plurality of display units while surrounding the plurality of display units contact the first mother substrate and the second mother substrate; irradiating a laser beam to the plurality of sealing portions so as to revolve around the plurality of display units along the plurality of sealing portions; and cutting the first mother substrate and the second mother substrate so as to obtain a plurality of display panels respectively including the display units, wherein the cutting of the first and second mother substrates comprises cutting along an outer side surface of a first part that is at least a part of the sealing portion extending along a display unit between two adjacent display units without a pad therebetween.

The plurality of pads may be respectively located outside the plurality of sealing portions.

The plurality of sealing portions may contact the first and second mother substrates in a state where a distance between an inner side surface of the first part of the sealing portion and the display unit is greater than a distance between an inner side surface of a second part that is at least a part of the sealing portion extending along another display unit of the two adjacent display units and the display unit.

Another aspect is a method of manufacturing a display device, that comprises: forming a plurality of display units and a plurality of pads corresponding to the plurality of display units on a first mother substrate; bonding the first mother substrate to a second mother substrate so that the plurality of display units are located inside, and a plurality of sealing portions disposed respectively outside the plurality of display units while surrounding the plurality of display units contact the first mother substrate and the second mother substrate; irradiating a laser beam to the plurality of sealing portions so as to revolve around the plurality of display units along the plurality of sealing portions; and cutting the first mother substrate and the second mother substrate so as to obtain a plurality of display panels respectively including the display units, wherein the plurality of sealing portions contact the first and second mother substrates in a state where a width of a first part that is at least a part of the sealing portion extending along a display unit, between two adjacent display units without a pad therebetween, is greater than a width of a second part that is at least a part of the sealing portion extending along another display unit of the two adjacent display units.

The plurality of pads may be respectively located outside the plurality of sealing portions.

The cutting may comprise cutting the first mother substrate and the second mother substrate along an outer side surface of the first part of the sealing portion.

Another aspect is a display device comprising: a first substrate; a display unit disposed over the first substrate; a second substrate located over the display unit; and a sealing portion disposed outside the display unit and between the first and second substrates, wherein the sealing portion includes a first part extending along a first edge of the first substrate, and wherein the first part comprises an outer side surface that is located on the same surface as an outer side surface of the first substrate.

The above display device further comprises a pad disposed over the first substrate to be adjacent to a third edge of the first substrate. In the above display device, the first edge extends in a first direction that crosses a direction in which the third edge extends. In the above display device, the sealing portion surrounds the display unit. The above display device further comprises a pad disposed over the first substrate to be adjacent to a third edge of the first substrate, wherein the pad is located outside the sealing portion. In the above display device, a first distance between an inner side surface of the first part of the sealing portion and the display unit is greater than a second distance between an inner side surface of a second part of the sealing portion and the display unit, and wherein the second part extends along a second edge of the first substrate that is opposite to the first edge of the first substrate. In the above display device, the sealing portion bonds the first substrate to the second substrate.

Another aspect is a display device comprising: a first substrate; a display unit disposed over the first substrate; a second substrate located over the display unit; and a sealing portion disposed outside the display unit and between the first substrate and the second substrate, wherein the sealing portion includes a first part extending along a first edge of the first substrate and having a width that is greater than a width of a second part of the sealing portion extending along a second edge of the first substrate that is opposite to the first edge of the first substrate.

The above display device further comprises a pad disposed over the first substrate to be adjacent to a third edge of the first substrate. In the above display device, the first edge extends in a first direction that crosses a direction in which the third edge extends. In the above display device, the sealing portion surrounds the display unit. The above display device further comprises a pad disposed over the first substrate to be adjacent to a third edge of the first substrate, wherein the pad is located outside the sealing portion. In the above display device, an outer side surface of the first part of the sealing portion is located on the same surface as an outer side surface of the first substrate. In the above display device, a first distance between an inner side surface of the first part of the sealing portion and the display unit is equal to a second distance between an inner side surface of the second part of the sealing portion and the display unit. The above display device further comprises a metal layer disposed between the first substrate and the sealing portion to correspond to the sealing portion, the metal layer having a width corresponding to the first part of the sealing portion to be greater than a width corresponding to the second part of the sealing portion. In the above display device, the sealing portion bonds the first substrate to the second substrate.

Another aspect is a method of manufacturing a display device, the method comprising: forming a plurality of display units and a plurality of pads corresponding to the display units over a first mother substrate; bonding the first mother substrate to a second mother substrate so that the display units are located inside, and a plurality of sealing portions disposed respectively outside the display units and surrounding the display units contact the first and second mother substrates; irradiating a laser beam to the sealing portions so as to revolve around the display units along the sealing portions; and cutting the first and second mother substrates so as to obtain a plurality of display panels respectively including the display units, wherein the cutting comprises cutting along an outer side surface of a first part of the sealing portion extending along a display unit between two adjacent display units without a pad disposed therebetween.

In the above method, the pads are respectively located outside the sealing portions. In the above method, the sealing portions contact the first and second mother substrates in a state where the distance between an inner side surface of the first part of the sealing portion and the display unit is greater than the distance between an inner side surface of a second part of the sealing portion extending along another display unit of the two adjacent display units and the display unit.

Another aspect is a method of manufacturing a display device, the method comprising: forming a plurality of display units and a plurality of pads corresponding to the display units over a first mother substrate; bonding the first mother substrate to a second mother substrate so that the display units are located inside, and a plurality of sealing portions disposed respectively outside the display units and surrounding the display units contact the first and second mother substrates; irradiating a laser beam to the sealing portions so as to revolve around the display units along the sealing portions; and cutting the first and second mother substrates so as to obtain a plurality of display panels respectively including the display units, wherein the sealing portions contact the first and second mother substrates in a state where the width of a first part of the sealing portion extending along a display unit, between two adjacent display units without a pad disposed therebetween, is greater than the width of a second part of the sealing portion extending along another display unit of the two adjacent display units.

In the above method, the pads are respectively located outside the sealing portions. In the above method, the cutting comprises cutting the first and second mother substrates along an outer side surface of the first part of the sealing portion.

Another aspect is a display device comprising: a first substrate; a display unit disposed over the first substrate; a second substrate located over the display unit; and a sealing portion disposed outside the display unit and between the first and second substrates, wherein the sealing portion includes a first part extending along a first edge of the first substrate, and wherein the first part comprises an outer side surface that overlaps an outer side surface of the first substrate and an outer side surface of the second substrate in the depth dimension of the display device.

In the above display device, the sealing portion further comprises a second part extending along a second edge of the first substrate that is opposite to the first edge of the first substrate, and wherein the first part has a width larger than that of the second part.

### BRIEF DESCRIPTION OF THE DRAWINGS

These and/or other aspects will become apparent and more readily appreciated from the following description of the exemplary embodiments, taken in conjunction with the accompanying drawings.

FIGS. 1 to 4 are plan views and cross-sectional views schematically illustrating processes of manufacturing a display device, according to an exemplary embodiment.

FIG. 5 is a schematic plan view of a display device according to an exemplary embodiment.

FIGS. 6 and 7 are schematic cross-sectional views illustrating processes of manufacturing a display device, according to a comparative example.

FIG. 8 is a schematic cross-sectional view of a display device according to another exemplary embodiment.

FIGS. 9 to 12 are schematic plan views and cross-sectional views illustrating processes of manufacturing a display device, according to another exemplary embodiment.

FIG. 13 is a schematic cross-sectional view of a display device according to another exemplary embodiment.

### DETAILED DESCRIPTION OF CERTAIN INVENTIVE EMBODIMENTS

Hereinafter, embodiments will be described in detail by explaining exemplary embodiments with reference to the attached drawings. Like reference numerals in the drawings denote like elements.

Sizes of components in the drawings may be exaggerated for convenience of explanation. In other words, since sizes and thicknesses of components in the drawings are arbitrarily illustrated for convenience of explanation, the following embodiments are not limited thereto. In this disclosure, the term “substantially” includes the meanings of completely, almost completely or to any significant degree under some applications and in accordance with those skilled in the art. Moreover, “formed, disposed over positioned over” can also mean “formed, disposed or positioned on.” The term “connected” includes an electrical connection.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another. As used herein, the term “and/or” includes any and all combinations of one or more of the associated listed items. Expressions such as “at least one of,” when preceding a list of elements, modify the entire list of elements and do not modify the individual elements of the list.

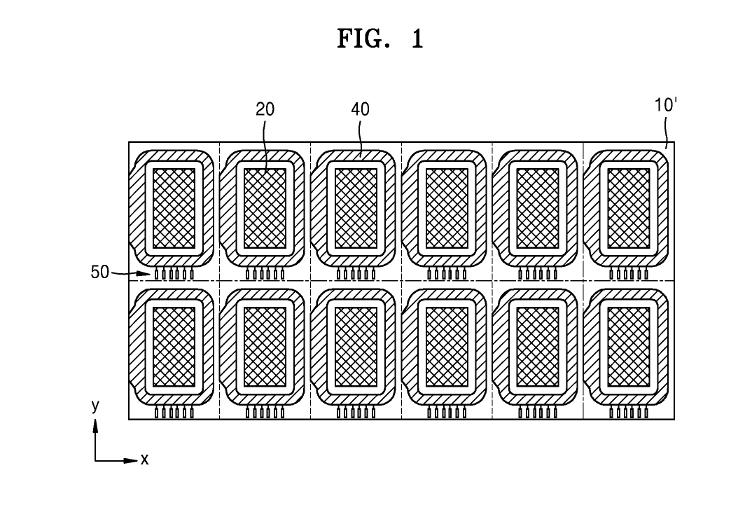

FIGS. 1 to 4 are schematic plan views and cross-sectional views illustrating processes of manufacturing a display device, according to an exemplary embodiment.

As shown in FIG. 1, a plurality of display units 20 and a plurality of pads 50 respectively corresponding to the display units 20 are formed on a first mother substrate 10′. The first mother substrate 10′ may include various materials, e.g., a polymer material such as polyimide or glass. Each of the display units 20 may include a display device such as an organic light-emitting diode or a liquid crystal device. The pads 50 are electrically connected to the display units 20 corresponding thereto in order to transfer electric signals to the display units 20.

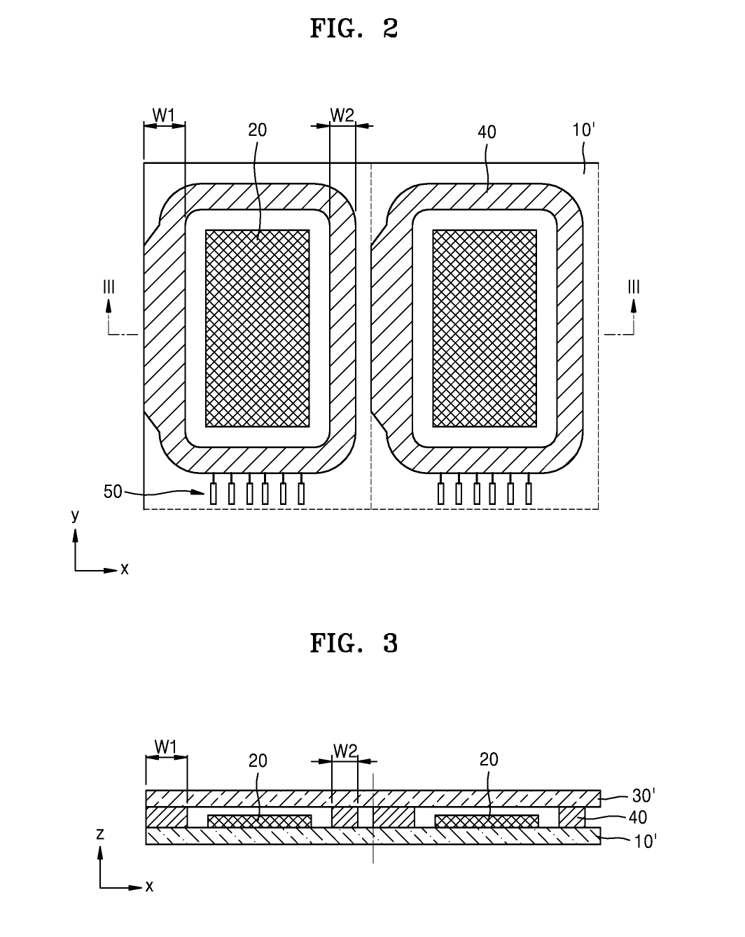

After that, the first mother substrate 10′ and a second mother substrate 30′ (see FIG. 3) are attached to each other, so that the display units 20 are located inside between the first mother substrate 10′ and the second mother substrate 30′. Here, a plurality of sealing portions 40 disposed respectively on outer portions of the display units 20 while surrounding the display units 20 contact the first and second mother substrates 10′ and 30′. In some embodiments, a material for forming the sealing portions 40, such as a sealant, is applied on the first mother substrate 10′, and then, the first and second mother substrate 10′ and 30′ may be attached to each other. Otherwise, the material for forming the sealing portions 40 may be applied on the second mother substrate 30′, and then, the first and second mother substrates 10′ and 30′ may be attached to each other. In either case, each of the sealing portions 40 may not have a constant width. In addition, the pads 50 are located on outer portions of the sealing portions 40.

As shown in FIG. 1 and FIGS. 2 and 3 showing some parts of FIG. 1, the pad 50 is disposed between two display units 20 that are adjacent to each other in an up-and-down direction (y-axis direction), and is not disposed between two display units 20 that are adjacent to each other in a left-and-right direction (x-axis direction). A part of the sealing portion 40 is disposed between the two adjacent display units 20 in the left-and-right direction (x-axis direction) so that the pad 50 is not disposed. For example, a part of the sealing portion 40 that is located in a −x direction of the display unit 20 at a right side between the two display units 20 of FIG. 2, may be considered to extend toward the display unit 20 in a left direction, which is located at −x direction of the display unit 20 at the right side. In addition, at least a part of the sealing portion 40 between the two adjacent display units 20 in the x-axis direction may be referred to as a first part P1 (see FIG. 5). In addition, a part of the sealing portion 40 that is located in a +x direction from the display unit 20 at the right side between the two display units 20 shown in FIG. 2 may be considered to extend along another display unit (which is not shown in FIG. 2) at a right side of the display unit 20. Furthermore, at least a part of the sealing portion 40 that is located in a +x direction from the display unit 20 at the right side between the two display units 20 may be referred to as a second part P2 (see FIG. 5).

Here, the first part P1 has a first width W1 and the second part P2 has a second width W2. The first width W1 can be greater than the second width W2. As described above, in a state where the sealing portion 40 includes the first and second parts P1 and P2, the first and second mother substrates 10′ and 30′ are attached to each other so that the sealing portions 40 contact the two substrates 10′ and 30′. The sealing portions 40 may be formed by applying a sealant via a nozzle.

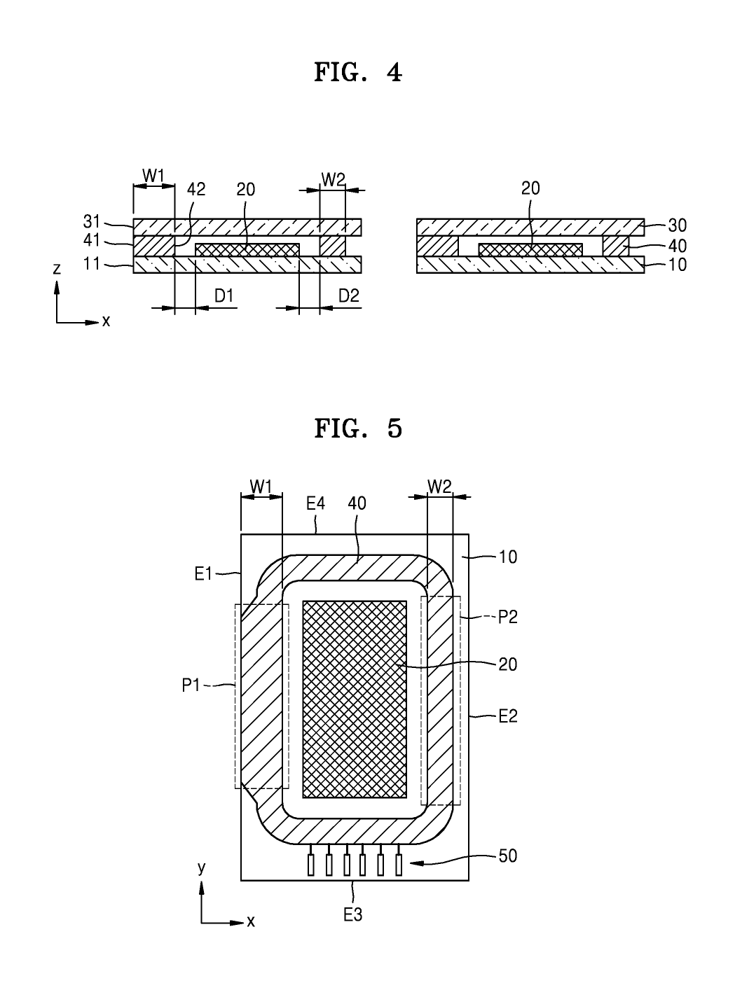

After that, a laser beam is irradiated to the sealing portions 40 so as to revolve around each of the display units 20 along the sealing portions 40, and then, the sealing portions 40 melt and/or harden. In addition, as shown in FIG. 4, the first and second mother substrates 10′ and 30′ are cut so as to obtain a plurality of display panels having the display units 20. Each of the display panels obtained as above includes a first substrate 10, a second substrate 30, the display unit 20 disposed between the first and second substrates 10 and 30, and the sealing portion 40 located on an outer portion of the display unit 20 and contacting the first and second substrates 10 and 30 while surrounding the display unit 20. Here, in the sealing portion 40, the first width W1 of the first part P1 in the −x direction can be greater than the second width W2 of the second part P2 in the +x direction.

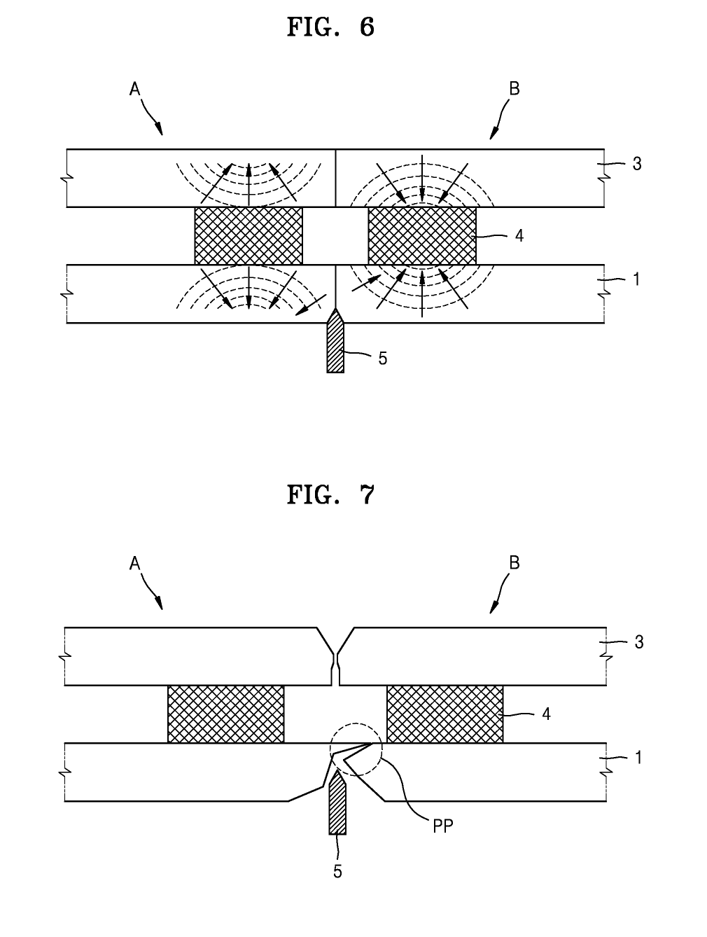

FIGS. 6 and 7 are schematic cross-sectional views illustrating processes of manufacturing a display device according to a comparative example. In FIG. 6, in a state where sealing portions 4 having constant widths are located between every two adjacent display regions, a first mother substrate 1 and a second mother substrate 3 are cut by a cutting wheel 5 at a center portion between the sealing portions 4. Here, the first mother substrate 1 and the second mother substrate 3 have distributions of internal stress denoted by dashed lines in FIG. 6.

When the display devices shown in FIG. 1 are manufactured at the same time, the laser beam is irradiated to the sealing portions 40 so as to revolve around each of the display units 20 along the sealing portions 40, as described above. For example, the laser beam starts to be irradiated onto a part of the sealing portion 40, which is adjacent to a right upper end of the display unit 20 corresponding to each of the sealing portions 40, and then, the laser beam is irradiated along the sealing portion 40. Accordingly, between the two adjacent display units 20, as shown in FIG. 2, the laser beam is irradiated first to the sealing portion 40 located in the −x direction and then irradiated onto the sealing portion 40 located in the +x direction.

When the laser beam is irradiated onto the sealing portion 40, the sealing portion 40 contracts. Therefore, when the laser beam is only irradiated to the sealing portion 40 in the −x direction and is not yet irradiated onto the sealing portion 40 in the +x direction at the sealing portion 40 between the two adjacent display units 40, as shown in FIG. 2, a distance between the first mother substrate 10′ and the second mother substrate 30′ around the sealing portion 40 in the −x direction is less than a distance between the first mother substrate 10′ and the second mother substrate 30′ around the sealing portion 40 in the +x direction. Accordingly, stress is applied to the first and second mother substrates 10′ and 30′. After that, when the laser beam is irradiated onto the sealing portion 40 in the +x direction, the distance between the first and second mother substrates 10′ and 20′ around the sealing portion 40 in the −x direction is substantially the same as the distance around the sealing portion 40 in the +x direction, but internal stress may exist in the first and second mother substrates 10′ and 30′ due to the stress applied to the substrates 10′ and 30′. The internal stress is distributed as denoted by dashed lines in FIG. 6.

In a state in which the internal stress is distributed in the first and second mother substrates 1 and 3 as described above, when the mother substrates 1 and 3 are cut at a center between the two sealing portions 4 by using the cutting wheel 5, the cutting may be performed abnormally as denoted by PP in FIG. 7 due to the internal stress in the substrates 1 and 3. This is because cracks may occur in the first mother substrate 1 in a direction perpendicular to the internal stress lines denoted by the dashed lines of FIG. 6.

However, according to the method of manufacturing the display device of the present exemplary embodiment, defects may be prevented or minimized. When cutting the first and second mother substrates 10′ and 30′ in a state shown in FIG. 3, the first and second mother substrates 10′ and 30′ are cut along an outer side surface of the first part P1 (see FIG. 5) of the sealing portion 40 in the −x direction that is opposite to the display unit 20 (+x direction). In FIG. 3, the cutting line is denoted by a dash-dot line. In this case, even if there is internal stress in the first and second mother substrates 10′ and 30′, as shown in FIG. 6, the sealing portion 40 is in contact with the first mother substrate 10′ until the sealing portion 40 is completely cut because the first width W1 of the sealing portion 40 in the −x direction of the display unit 20 at the right side of FIGS. 3 and 4 is wide. Thus, the cracks that may occur in the first mother substrate 1 toward the display unit 20, as shown in FIG. 7, may be prevented effectively.

In addition, referring to FIG. 1, the sealing portions 40 between the two adjacent display units 20 in the up-and-down direction (y-axis direction) have widths that are substantially equal to each other. Since the pad 50 is located between the two adjacent display units 20 in the up-and-down direction, the sealing portion 40 adjacent to the display unit 20 in a +y direction is sufficiently spaced apart from the sealing portion 40 adjacent to the display unit 20 in a −y direction. That is, as shown in FIG. 6, even if there is internal stress in the first and second mother substrates 1 and 3 around the sealing portions 4, cutting defects may not occur or rarely occur due to the internal stress when they are cut between the adjacent sealing portions 4, provided that the adjacent sealing portions 4 are far from each other. Therefore, as shown in FIG. 1, even when the sealing portions 40 between the two adjacent display units 20 in the y-axis direction have equal widths, cutting defects may not occur or rarely occur.

The display device according to an exemplary embodiment may have a structure illustrated in FIGS. 4 and 5. In particular, the display device according to the present exemplary embodiment includes the first substrate 10, the display unit 20 disposed on the first substrate 10, the second substrate 30 disposed above the first substrate 10 so that the display unit 20 is located therein, and the sealing portion 40 disposed between the first substrate 10 and the second substrate 30.

Here, the sealing portion 40 is outside the display unit 20. In addition, the first width W1 of the first part P1 that is at least a part of the sealing portion 40 extending along a first edge E1 of the first substrate 10 can be greater than the second width W2 of the second part P2 that is at least a part of the sealing portion 40 extending along a second edge E2 that is opposite to the first edge E1 of the first substrate 10. In addition, the pad 50 is disposed on the first substrate 10 to be adjacent to a third edge E3 from among four edges E1 to E4 of the first substrate 10, and is located outside the sealing portion 40 that surrounds the display unit 20. Here, a direction in which the third edge E3 (x-axis direction) crosses a direction, in which the first edge E1 or the second edge E2 extends (y-axis direction).

In the display device according to the present exemplary embodiment, since the first part P1 of the sealing portion 40 has a greater first width W1, a contact area between the first part P1 of the sealing portion 40 and the first substrate 10 and/or the second substrate 30 is sufficiently large. Therefore, defects such as cracks occurring in the first substrate 10 and/or the second substrate 30 during the manufacturing processes may be effectively prevented. In particular, an outer side surface 41 of the first part P1 of the sealing portion in a direction (−x direction) opposite to the display unit 20 (+x direction) may be on the same surface (e.g., same plane) as an outer side surface 11 of the first substrate 10 and/or an outer side surface 31 of the second substrate 30, and accordingly, defects such as cracks in the first and second substrates 10 and 30 may be effectively prevented. For example, as shown in FIG. 4, an outer side surface 41 of the first part P1 overlaps or aligns an outer side surface 31 of the first substrate 10 and an outer side surface 31 of the second substrate 30 in the depth dimension of the display device.

Although the sealing portion 40 has a width that varies depending on locations thereof, a distance D1 between an inner side surface 42 of the first part P1 of the sealing portion 40 in the display unit 20 direction (+x direction) and the display unit 20 is substantially equal to a distance D2 between an inner side surface of the second part P2 of the sealing portion 40 in the display unit 20 direction and the display unit 20.

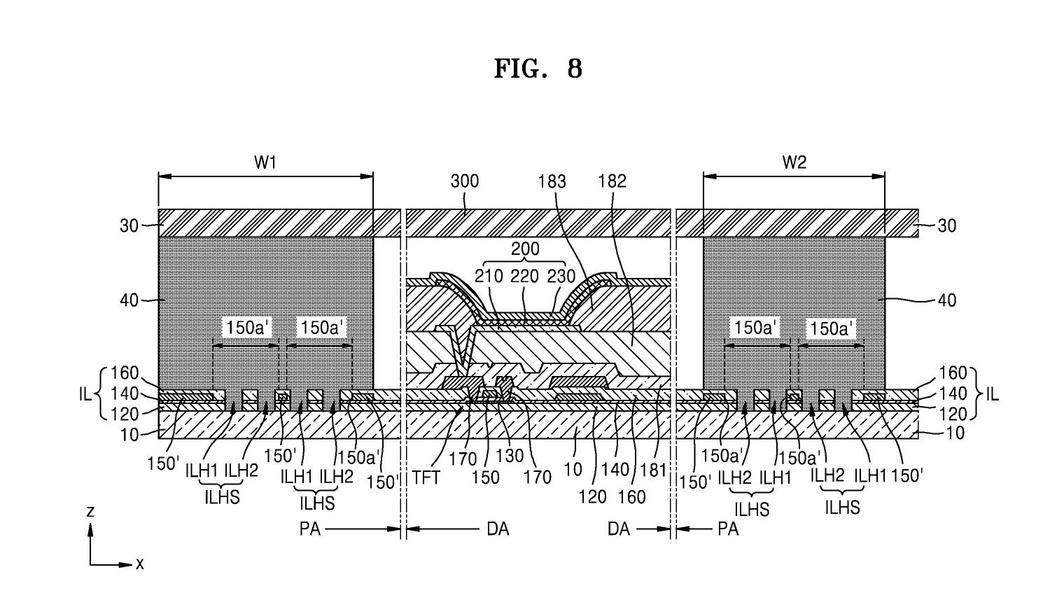

FIG. 8 is a schematic plan view of a display device according to an exemplary embodiment, and in particular, FIG. 8 schematically shows an organic light-emitting display device.

The organic light-emitting diode (OLED) display according to the exemplary embodiment includes an OLED 200 including a pixel electrode 210, an intermediate layer 220 including an emission layer, and an opposite electrode 230 on a display area DA, and the OLED 200 is electrically connected to a thin film transistor TFT thereunder to control light emission. The thin film transistor TFT includes a semiconductor layer 130, a gate electrode 150, and source/drain electrodes 170. The thin film transistor TFT is located on a buffer layer 120 on the first substrate 10, a gate insulating layer 140 is disposed between the semiconductor layer 130 and the gate electrode 150, and an inter-insulating layer 160 is disposed between the gate electrode 150 and the source/drain electrodes 170. In addition, if necessary, a protective layer 181 covers the thin film transistor TFT, a planarization layer 182 planarizes an upper surface of the protective layer 181, and the pixel electrode 210 is located on the planarization layer 182. A pixel-defining layer 183 defining an emission area of a pixel may cover edges of the pixel electrode 210.

The buffer layer 120, the gate insulating layer 140, and the inter-insulating layer 160 on the display area DA may extend to a peripheral area PA outside the display area DA, and the buffer layer 120, the gate insulating layer 140, and the inter-insulating layer 160 all may be referred to as insulating layers IL. The insulating layers IL include a plurality of through hole sets ILHS in a lower portion of the sealing portion 40, and each of the plurality of through hole sets ILHS may include a plurality of through holes ILH1 and ILH2. In addition, a metal layer 150′ that may include the same material as that of the gate electrode 150 on the display area DA at the same time may be located on the lower portion of the sealing portion 40. The metal layer 150′ includes through openings 150a′, and the through openings 150a′ may respectively correspond to the through hole sets ILHS.

In the above OLED display, the first width W1 of the sealing portion 40 in the −x direction can be greater than the second width W2 of the sealing portion 40 in the +x direction, and accordingly, a contact area between the first part P1 of the sealing portion 40 and the first substrate 10 and/or the second substrate 30 is sufficiently large. Therefore, defects such as cracks occurring in the first substrate 10 and/or the second substrate 30 during the manufacturing processes may be prevented effectively. Here, the metal layer 150′ in the lower portion of the sealing portion 40 may correspond to the width of the sealing portion 40. In some embodiments, a width of the metal layer 150′ in the −x direction is substantially equal to the first width W1 that is greater than the second width W2 that is equal to a width of the metal layer 150′ in the +x direction. When the laser beam is irradiated onto the sealing portion 40, the metal layer 150′ reflects the laser beam that has passed through the sealing portion 40 toward the sealing portion 40 again, thereby improving an irradiation efficiency of the laser beam.

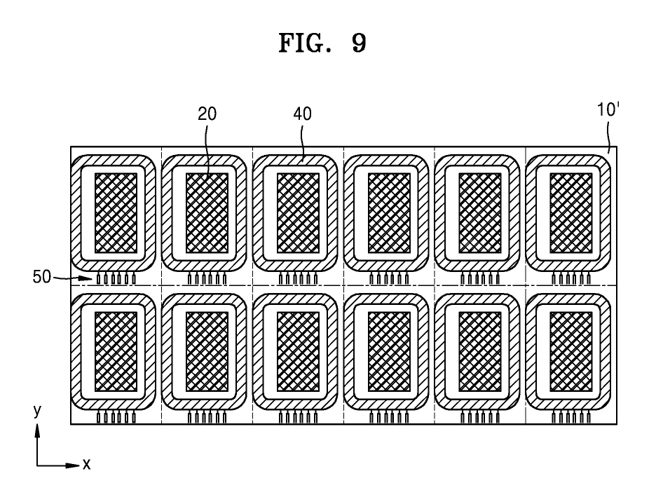

FIGS. 9 to 12 are schematic plan views and cross-sectional views illustrating processes of manufacturing a display device, according to another exemplary embodiment.

As shown in FIG. 9, the display units 20 and the pads 50 respectively corresponding to the display units 20 are formed on the first mother substrate 10′.

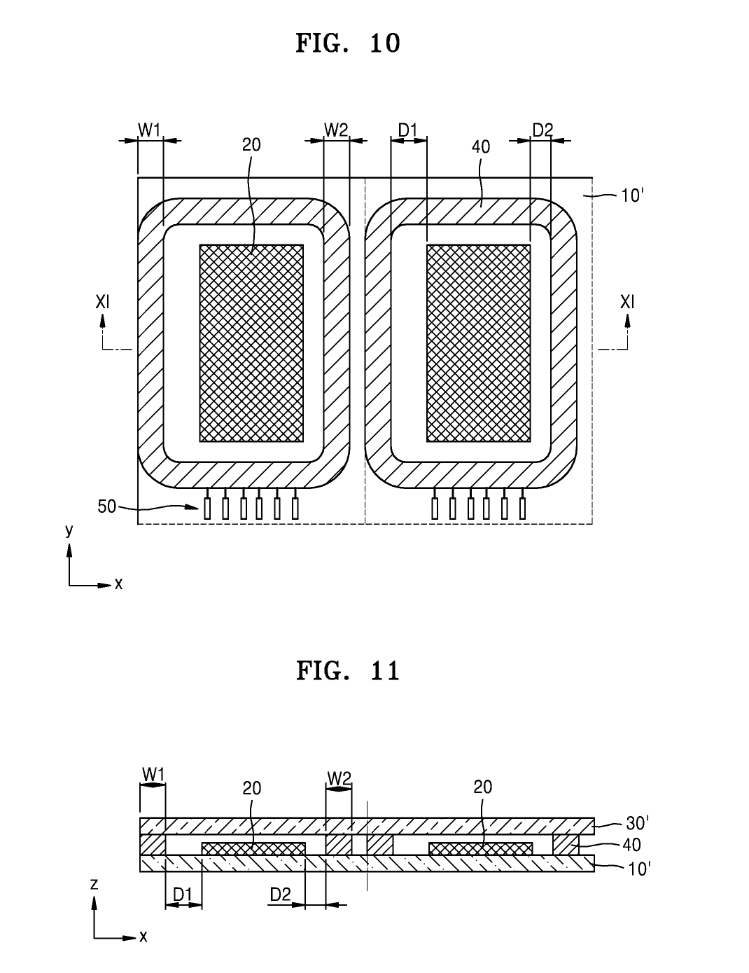

After that, the first mother substrate 10′ and the second mother substrate 30′ (see FIG. 11) are attached to each other so that the display units 20 are located inside between the first and second mother substrates 10′ and 30′. Here, the sealing portions 40 disposed respectively on outer portions of the display units 20 while surrounding the display units 20 contact the first mother substrate 10′ and the second mother substrate 30′. In some embodiments, a material for forming the sealing portions 40 such as a sealant is applied on the first mother substrate 10′, and after that, the first and second mother substrates 10′ and 30′ may be attached to each other. Otherwise, the first and second mother substrates 10′ and 30′ may be attached to each other after applying the material for forming the sealing portions 40 on the second mother substrate 30′. Each of the sealing portions 40 may have a constant width W1 and W2 (see FIG. 10). In addition, as shown in FIG. 9 and FIG. 10 showing a part of FIG. 9, the pad 50 is disposed between two adjacent display units 20 in an up-and-down direction (y-axis direction), and is not disposed between two adjacent display units 20 in a left-and-right direction (x-axis direction). Here, the plurality of pads 50 are located at outside the sealing portions 40.

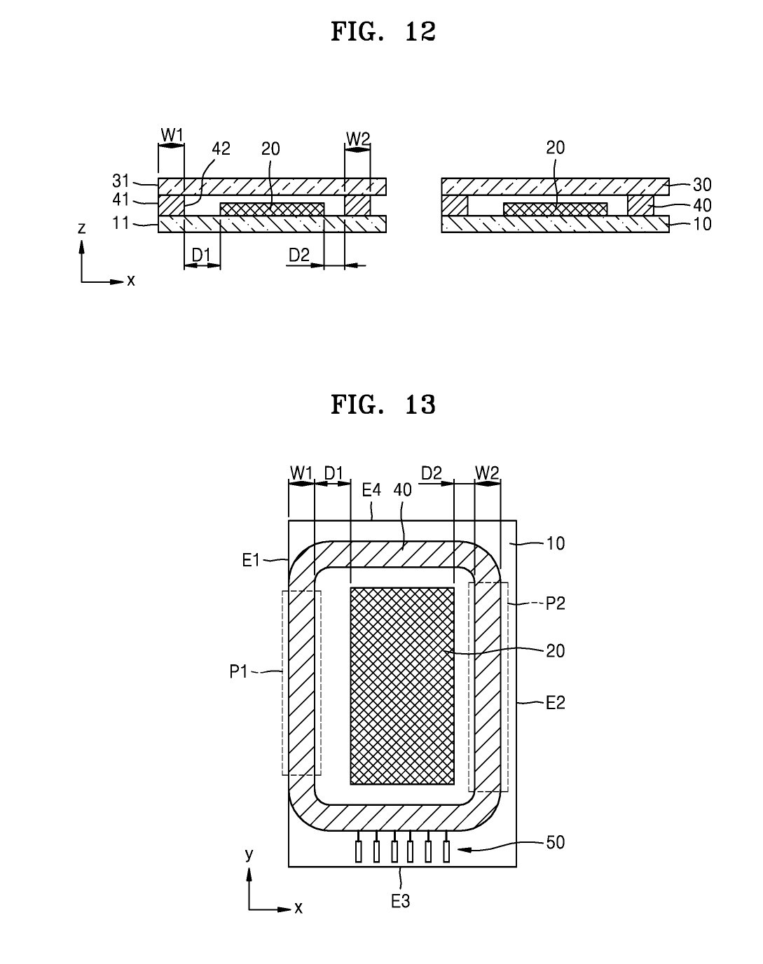

In addition, the laser beam is irradiated respectively onto the sealing portions 40 while revolving around the sealing display units 20 along the sealing portions 40, and then, the sealing portions 40 melt and/or harden. In addition, as shown in FIG. 12, the first mother substrate 10′ and the second mother substrate 30′ are cut to obtain a plurality of display panels respectively having the display units 20. Here, a cutting location of the first and second mother substrates 10′ and 30′ between the display units 20 is denoted by a dash-dot line in FIG. 11. In some embodiments, the cutting location of the first and second mother substrates 10′ and 30′ is between the two adjacent display units 20 without the pad 50 therebetween, that is, an outer side surface of the first part P1 (see FIG. 13) in a direction (−x direction) opposite to the display unit 20 (+x direction), wherein the first part P1 is at least a part of the sealing portion 40 extending along the display unit 20 (in FIG. 11, the display unit 20 in the +x direction).

As described above with reference to FIGS. 6 and 7, when the first mother substrate 1 and the second mother substrate 3 are cut by the cutting wheel 5 at the center between the sealing portions 4 in a state where the internal stress is distributed in the first mother substrate 1 and the second mother substrate 3, the cutting may be performed abnormally as denoted by PP in FIG. 7 due to the internal stress in the first and second mother substrates 1 and 3. Because cracks may occur in the first mother substrate 1 in a direction perpendicular to the internal stress denoted in FIG. 6.

However, according to the method of manufacturing the display device of the present exemplary embodiment, defects may be prevented or minimized. When cutting the first and second mother substrates 10′ and 30′ in a state illustrated in FIG. 11, the first and second mother substrates 10′ and 30′ are cut along the outer side surface of the first part P1 (see FIG. 13) of the sealing portion 40 in the direction (−x direction) opposite to the display unit 20 (+x direction). In FIG. 11, the cutting line is denoted by a dash-dot line. In this case, even when the internal stress illustrated in FIG. 6 exists in the first and second mother substrates 10′ and 30′, the sealing portion 40 is in contact with the first mother substrate 10′ to the cutting line, and thus, generation of cracks in the first mother substrate 1 toward the display unit as shown in FIG. 7 may be prevented.

Between the two display units 20 shown in FIG. 10, a part of the sealing portion 40 located in −x direction of the display unit 20 at the right side may be considered to extend along the display unit 20 at the left side, which is located in the −x direction of the sealing portion 40, and at least a part of the sealing portion 40 may be referred to as the first part P1 (see FIG. 13). In addition, between the two display units 20 in FIG. 10, a part of the sealing portion 40 located in +x direction of the display unit 20 at the right side may be considered to extend along the display unit 20 at the right side (omitted in FIG. 10), which is located in the +x direction of the sealing portion 40, and at least a part of the sealing portion may be referred to as the second part P2 (see FIG. 13).

As shown in FIG. 10, the sealing portion 40 has the widths W1 and W2 that are equal to each other. Therefore, in order to locate the display unit 20 at the center of the first substrate 10 (see FIG. 12) in the x-axis direction, a distance D1 between an inner side surface 42 (see FIG. 12) of the first part P1 (see FIG. 13) in the display unit 20 direction and the display unit 20 needs to be greater than a distance D2 between an inner side surface of the second part P2 in a direction toward the display unit 20 and the display unit 20.

The display device according to the exemplary embodiment may have the structure illustrated in FIGS. 12 and 13. For example, the display device according to the present exemplary embodiment includes the first substrate 10, the display unit 20 disposed on the first substrate 10, the second substrate 30 located above the first substrate 10 so that the display unit 20 may be located therein, and the sealing portion 40 disposed between the first and second substrates 10 and 30.

Here, the sealing portion 40 is disposed outside the display unit 20, and the first part P1 that is at least a part of the sealing portion 40 extending along the first edge E1 from among edges of the first substrate 10 has an outer side surface in a direction (−x direction) opposite to the display unit 20 (+x direction) located at the same surface (e.g., same plane) as the outer side surface of the first substrate 10. In addition, the pad 50 is disposed on the first substrate 10 to be adjacent to the third edge E3 from among the edges E1 to E4 of the first substrate 10, and is located outside the sealing portion 40 that surrounds the display unit 20. Here, a direction in which the third edge E3 extends (x-axis direction) crosses a direction in which the first edge E1 extends (y-axis direction).

In the display device according to the present exemplary embodiment, since the outer side surface 41 of the first part P1 in the sealing portion 40 is located at the same plane as the outer side surface of the first substrate 10, the first part P1 is in contact with an end portion of the edge of the first substrate 10 and/or the second substrate 30. Accordingly, defects such as cracks occurring in the outer side surface of the first substrate 10 and/or the second substrate 30 during the manufacturing process may be prevented.

In addition, although the sealing portion 40 has the widths W1 and W2 that are substantially equal to each other, the distance D1 between the inner side surface 42 of the first part P1 of the sealing portion in the direction toward the display unit 20 (+x direction) and the display unit 20 can be greater than the distance D2 between the inner side surface of the second part P2 of the sealing portion in the direction toward the display unit 20 and the display unit 20, so that the first part P1 of the sealing portion 40 may contact the end portion of the edge in the first substrate 10 and/or the second substrate 30 and the display unit 20 may be located at the center of the first substrate 10 in the x-axis direction.

According to at least one of the disclosed embodiments, the display device can reduce a defect rate during manufacturing.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details may be made therein without departing from the spirit and scope as defined by the following claims.

What is claimed is:

1. A display device comprising:
a first substrate;
a display unit disposed over the first substrate;
a second substrate located over the display unit; and
a sealing portion disposed outside the display unit and between the first and second substrates, wherein the sealing portion includes a first part extending along a first edge of the first substrate, and wherein the first part comprises an outer side surface that is located on the same surface as an outer side surface of the first substrate.

2. The display device of claim 1, further comprising a pad disposed over the first substrate to be adjacent to a third edge of the first substrate.

3. The display device of claim 2, wherein the first edge extends in a first direction that crosses a direction in which the third edge extends.

4. The display device of claim 1, wherein the sealing portion surrounds the display unit.

5. The display device of claim 4, further comprising a pad disposed over the first substrate to be adjacent to a third edge of the first substrate, wherein the pad is located outside the sealing portion.

6. The display device of claim 1, wherein a first distance between an inner side surface of the first part of the sealing portion and the display unit is greater than a second distance between an inner side surface of a second part of the sealing portion and the display unit, and wherein the second part extends along a second edge of the first substrate that is opposite to the first edge of the first substrate.

7. The display device of claim 1, wherein the sealing portion bonds the first substrate to the second substrate.

8. A display device comprising:
a first substrate;
a display unit disposed over the first substrate;
a second substrate located over the display unit; and
a sealing portion disposed outside the display unit and between the first substrate and the second substrate, wherein the sealing portion includes a first part extending along a first edge of the first substrate and a second part extending along a second edge of the first substrate that is opposite to the first edge of the first substrate, and wherein the first part has a width that is greater than a width of the second part.

9. The display device of claim 8, further comprising a pad disposed over the first substrate to be adjacent to a third edge of the first substrate.

10. The display device of claim 9, wherein the first edge extends in a first direction that crosses a direction in which the third edge extends.

11. The display device of claim 8, wherein the sealing portion surrounds the display unit.

12. The display device of claim 11, further comprising a pad disposed over the first substrate to be adjacent to a third edge of the first substrate, wherein the pad is located outside the sealing portion.

13. The display device of claim 8, wherein an outer side surface of the first part of the sealing portion is located on the same surface as an outer side surface of the first substrate.

14. The display device of claim 8, wherein a first distance between an inner side surface of the first part of the sealing portion and the display unit is equal to a second distance between an inner side surface of the second part of the sealing portion and the display unit.

15. The display device of claim 8, further comprising a metal layer disposed between the first substrate and the sealing portion to correspond to the sealing portion, the metal layer having a width corresponding to the first part of the sealing portion to be greater than a width corresponding to the second part of the sealing portion.

16. The display device of claim 8, wherein the sealing portion bonds the first substrate to the second substrate.

17. A method of manufacturing a display device, the method comprising:
forming a plurality of display units and a plurality of pads corresponding to the display units over a first mother substrate;
bonding the first mother substrate to a second mother substrate so that the display units are located inside, and a plurality of sealing portions disposed respectively outside the display units and surrounding the display units contact the first and second mother substrates;
irradiating a laser beam to the sealing portions so as to revolve around the display units along the sealing portions; and
cutting the first and second mother substrates so as to obtain a plurality of display panels respectively including the display units,
wherein the cutting comprises cutting along an outer side surface of a first part of the sealing portion extending along a display unit between two adjacent display units without a pad disposed therebetween.

18. The method of claim 17, wherein the pads are respectively located outside the sealing portions.

19. The method of claim 17, wherein the sealing portions contact the first and second mother substrates in a state where the distance between an inner side surface of the first part of the sealing portion and the display unit is greater than the distance between an inner side surface of a second part of the sealing portion extending along another display unit of the two adjacent display units and the display unit.

20. A method of manufacturing a display device, the method comprising:
forming a plurality of display units and a plurality of pads corresponding to the display units over a first mother substrate;
bonding the first mother substrate to a second mother substrate so that the display units are located inside, and a plurality of sealing portions disposed respectively outside the display units and surrounding the display units contact the first and second mother substrates;
irradiating a laser beam to the sealing portions so as to revolve around the display units along the sealing portions; and
cutting the first and second mother substrates so as to obtain a plurality of display panels respectively including the display units,
wherein the sealing portions contact the first and second mother substrates in a state where the width of a first part of the sealing portion extending along a display unit, between two adjacent display units without a pad disposed therebetween, is greater than the width of a second part of the sealing portion extending along another display unit of the two adjacent display units.

21. The method of claim 20, wherein the pads are respectively located outside the sealing portions.

22. The method of claim 20, wherein the cutting comprises cutting the first and second mother substrates along an outer side surface of the first part of the sealing portion.

23. A display device comprising:
a first substrate;
a display unit disposed over the first substrate;
a second substrate located over the display unit; and
a sealing portion disposed outside the display unit and between the first and second substrates, wherein the sealing portion includes a first part extending along a first edge of the first substrate, and wherein the first part comprises an outer side surface that overlaps an outer side surface of the first substrate and an outer side surface of the second substrate in the depth dimension of the display device.

24. The display device of claim 23, wherein the sealing portion further comprises a second part extending along a second edge of the first substrate that is opposite to the first edge of the first substrate, and wherein the first part has a width larger than that of the second part.
